(19) United States
(12) Patent Application Publication
(10) Pub. No.: US 2002/0017828 A1
(43) Pub. Date: Feb. 14, 2002

(54) Substrate lamina made of langasite or langatate

(75) Inventor: Ulrike Roesler, Erding (DE)

Correspondence Address: BAKER & BOTTS, 30 ROCKEFELLER PLAZA, NEW YORK, NY, 10112

(73) Assignee: SIEMENS AG.

(21) Appl. No.: 09/923,733

(22) Filed: Aug. 7, 2001

Related U.S. Application Data
(63) Continuation of application No. PCT/DE00/00470, filed on Feb. 18, 2000.

(30) Foreign Application Priority Data
Feb. 23, 1999 (DE) DE 199 07 761.4

(51) Int. Cl. H01L 41/04

(52) U.S. Cl. 310/313 A; 310/313 R; 310/360

(57) ABSTRACT

Substrate lamina made of langasite or langatate with a crystal cut (X₁, X₂, X₃) for langasite in a range around the Euler angle combination (100°, 1400°, 166°) or the Euler angle combinations equivalent thereto, or respectively with special angle combinations of langatate.

### BACKGROUND OF THE INVENTION

Langasite and langatate are used as crystal materials, like quartz, lithium niobate, lithium tantalate etc., as substrate laminas for surface acoustic wave components. Such surface acoustic wave components are used as (radiofrequency) filters, delay lines, identification marks and sensors for a wide variety of applications. On at least one flat surface of the substrate lamina, electrode structures of a particular predetermined type and design are applied for a saw. Acoustic waves can be produced in the flat surface of the crystal by means of transducer electrode structures when an electrical signal is applied. These waves have a particular waveform according to the existent boundary conditions in particular, Rayleigh waves, shear waves, etc. Such a wave propagates at the surface with a material-specific velocity that also depends on the crystal cut and may also be dependent on the respective temperature of the crystal. If these electrode structures form an electro-acoustic resonant system, then the frequency stability of such a surface acoustic wave (saw) component is also temperature-dependent. For a particular crystal cut, the crystal material may have the characteristic that the principal wave propagation direction, which is determined per se by the chosen structure of the transducer system, is actually offset by a beam steering angle.

Jpn. J. Appl. Phys. 37 (1998) 2909 and DE 195 32 602 Cl have already disclosed crystal cuts, for SAW substrate laminas, that are regarded as suitable, i.e. chosen, for certain applications. In particular, the latter publication indicates the temperature characteristic of individual langasite crystal cuts. These are crystal cuts that, specifically for temperature sensors, exhibit a particularly high temperature dependency of the electrical component values. Special crystal cuts for filters, etc. are described in WO 97/25776 Al with Euler angles λ=−15° to +10°, μ=120° to 165° and 0 =20° to 45°. The IEEE Frequ. Control. Symp. (1998) 742 reference also relates to langasite.

### SUMMARY OF THE INVENTION

It is an object of the present invention to find crystal cuts for substrate laminas for surface acoustic wave components that have a large coupling factor, small surface wave propagation velocity of the (chosen) surface wave, and a beam steering angle that tends, as far as possible, toward zero. Surface acoustic wave components having these crystal cuts which exhibit these three characteristics are intended to be temperature-stable, preferably temperature-invariant, and to have a high frequency stability as resonant components. With a high coupling factor, it is possible to achieve large filter bandwidths. In particular, in the case of a crystal cut according to the present invention, the propagation velocity of a bulk wave is substantially greater than the low transmission velocity for the known surface wave in the crystal cut, of the surface acoustic wave component. This object of the present invention is achieved with crystal cuts having Euler angle combinations as disclosed hereinbelow.

Langasite and langatate, having the composition La₃Ga₅SiO₁₄, or La₃Ga_{5.5}Ta_{0.5}O₁₄, respectively, each form a trigonal crystal, i.e. they have a crystal unit cell of trigonal symmetry with a non-perpendicular x, y, z coordinate system in which the axes are at angles of 120°, 90°, 90° with respect to one another. As a basis for recording and specifying the individual material values and their further use, this crystal coordinate cuts having Euler angle combinations as disclosed hereinbelow.

Langasite and langatate, having the composition La₃Ga₅SiO₁₄, or La₃Ga_{5.5}Ta_{0.5}O₁₄, respectively, each form a trigonal crystal, i.e. they have a crystal unit cell of trigonal symmetry with a non-perpendicular x,y,z coordinate system in which the axes are at angles of 120°,90°,90° with respect to one another. As a basis for recording and specifying the individual material values and their further use, this crystal coordinate system is assigned a right-angled coordinate system, here denoted by X, Y and Z. In this case, the Z axis is defined as coinciding with the z axis and the X axis as coinciding with the x axis, or with the respective axes being aligned parallel to one another. In this context, reference is made to Standards on Piezoelectric Crystals (1949), and Nye, “Physical Properties of Crystal,” Oxford Science Publications, CLARENDON Press Oxford (1985), Appendix B, in particular pages 276 to 281.

A choice is to be made regarding the orientation with which a substrate lamina having a particular surface which is intended for the excitation of a surface wave. To identify this crystal cut and this direction, the surface of the substrate lamina is assigned its own right-angled axis system, here denoted by x₁, x₂ and x₃. The unique correspondence between the right-angled crystal coordinate system X, Y, Z and this axis system x₁, x₂ and x₃ is defined and uniquely established quantitatively, in the known way by respectively specifying the Euler angles λ, μ and θ.

For a substrate lamina of a surface acoustic wave component, or for the surface provided with the structures, the x₁ direction is defined as the principal wave propagation direction (with beam steering angle =0) as determined by the transducer structure.

The present invention is further described in detail below in conjunction with the following figures, in which:

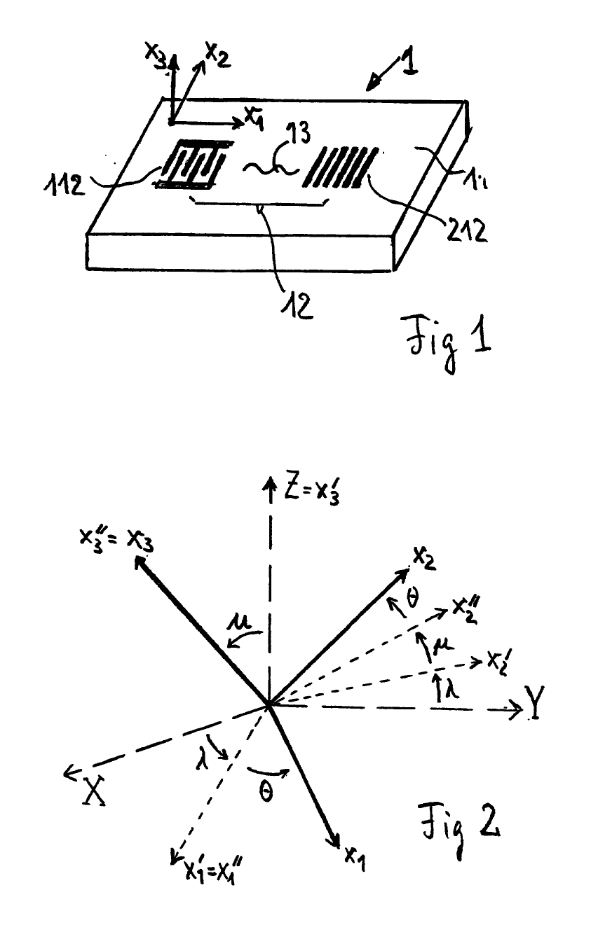

FIG. 1 shows a schematic representation of a piezoelectric surface acoustic wave component, or, more precisely, its substrate lamina; and

FIG. 2 shows the right-angled coordinate system X, Y, Z of the crystal and the position of the Euler angles.

### DETAILED DESCRIPTION OF THE INVENTION

In FIG .1, 10 denotes the langasite of langatate crystal lamina of the surface acoustic wave component 1. A surface acoustic wave structure 12 which in simplified form comprises a transducer structure 112 and a reflector structure 212, is represented on the chosen surface 11. When an electrical signal is applied to the transducer structure, an acoustic wave 13 can be produced in the surface 11. This wave (having a beam steering angle = 0) is transmitted in the principle wave propagation direction specified by the axis x₁. The other axes x₂ and x₃ are oriented orthogonally thereto. This axis system x₁, x₂, x₃ identifies the crystal cut of the surface 11.

In FIG. 2, the axes X, Y and Z of the crystal are represented in a perspective view. The axes x₁ and x₃ of the crystal cut of the surface 11 in FIG. 1 are also indicated in the crystal coordinate system. This orientation of the crystal cut axes with respect to the crystal axes X, Y, Z is uniquely described by the Euler angles λ, μ and θ. From this crystal coordinate system X, Y, Z the three, by definition successive, angular rotations λ, μ and θ provide the orientation of the axis system x₁, x₂, x₃. To that end, the plane of the axes X and Y is firstly rotated by the angle λ about the axis Z. This gives the axis system x₁′, x₂′, x₃′ as an intermediate stage. The plane containing the Z axis and the x₂′ axis is then rotated by the angle μ about the axis x₁′. This gives the axis arrangement x₁′=x₁Δ, x₂′,x₃′. Using the third Euler angle θ, the plane containing the axes x₁′ and x₂′ is then rotated about the axis x₃′ and this gives the axis system x₁, x₂, x₃ of the crystal cut, i.e. of the surface 11.

Crystal cuts having a high coupling factor and low, (not very temperature-dependent), propagation velocity of the acoustic surface wave 13, and hence having high frequency stability of a langasite component [lacuna] are defined by Euler angles which have the respective ranges λ=10° to 14°; μ=130° to 150°; and θ greater than 160° to 175°. Crystal cuts with Euler angles falling within these ranges, and all crystallographically equivalent combination thereof, have very low linear temperature coefficents for the relatively low propagation velocity v, i.e., about 2680 m/s for the acoustic wave 13, and for the electro-acoustic coupling factor, of about 0.45 to 0.5% that is high relative thereto. A low wave velocity makes is possible to produce a surface acoustic wave component having a predetermined characteristic even with a comparatively short substrate lamina. Owing to the high coupling factor, such a component has a higher achievable frequency bandwidth with comparatively low insertion attenuation.

A further feature of the present invention is that the beam steering angle is particularly small for a component with Euler angles of the crystal cut that fall within said angle ranges. A selection of a combination of Euler angles for langasite which is particularly favorable is one having (λ,μ, θ)=(10°, 140°,166°) with a tolerance width of ±35° for the angles μ and θ. The angle μ should as far as possible by kept within the production accuracy of the crystal cut. Crystallographically equivalent combinations, including said tolerance widths, should be interpreted as meaning that this crystal cut corresponds to the indicated combination or to a combination crystallographically equivalent thereto as defined below.

Characterizing the aforesaid angle combination (10°, 140°, 166°) a 1₀, mₘ, t₀, where 1, m and t stand for λ, μ and θ, crystallographic.

Equivalents to 1₀, m₀, t₀ are:

| | |
|---|---|
| (1₀, m₀, t₀ + 180°) | (10°, 140°, 346°) |
| (1₀, m₀ + 180° − t₀) | (10°, 320°, 14°) |
| (1₀, m₀ + 180°, 360° − t₀) | 10°, 320°, 194°) |
| (1₀ + 120°, m₀, t₀) | (130°, 140°, 166°) |
| (1₀ + 120°, m₀, t₀ + 180°) | (130°, 140°, 346°) |
| (1₀ + 120°, m₀ + 180°, 180° − t₀) | (130°, 320°, 14°) |
| (1₀ + 120°, m₀+ 180°, 360° − t₀) | (130°, 320°, 194°) |

and, correspondingly, the combinations as indicated below:

| | |
|---|---|
| (250°, 140°, 166°) | (110°, 140°, 14°) |
| (250°, 140°, 346°) | (110°, 140°, 194°) |
| (250°, 320°, 14°) | (110°, 320°, 166°) |
| (250°, 320°, 194°) | (110°, 320°, 346°) |
| (230°, 140°, 14°) | (350°, 140°, 14°) |
| (230°, 140°, 194°) | (350°, 140°, 194°) |
| (230°, 320°, 166°) | (350°, 320°, 166°) |
| (230°, 320°, 346°) | (350°, 320°, 346°) |
| (50°, 220°, 14°) | (70°, 220°, 166°) |
| (50°, 220°, 194°) | (70°, 220°, 346°) |
| (50°, 40°, 166°) | (70°, 40°, 14°) |
| (50°, 40°, 346°) | (70°, 40°, 194°) |
| (170°, 220°, 14°) | (190°, 220°, 166°) |
| (170°, 220°, 194°) | (190°, 220°, 346°) |
| (170°, 40°, 166°) | (190°, 40°, 14°) |
| (170°, 40°, 346°) | (190°, 40°, 194°) |
| (290°, 220°, 14°) | (310°, 220°, 166°) |
| (290°, 220°, 194°) | (310°, 220°, 346°) |
| (290°, 40°, 166°) | (310°, 40°, 14°) |
| (290°, 40°, 346°) | (310°, 40°, 194°) |

Langatate, as a monocrystalline material for substrate laminas for surface acoustic wave elements, has other combinations of Euler angles for achieving the object of the present invention and which are indicated below. Langatate crystal cuts with high coupling factor and especially low propagation velocity, as well as a beam steering angle lying at least approximately at the value zero, are (λ₀, μ₀, θ₀) as follows:

(0°, 80° to 110°, 0°)with tolerance range ±5° for λ and θ,

(0°, 20° to 80°, 32.5°±5°)

(0° to 20°, 130° to 150°, 155° to 180°)

(30°, 60°, 0°) in each case with ±5° angle tolerance

(10°±5°, 35°±10°, 26°±5°)

(20°±5°, 30° to 70°, 17°±5°)

and, in each case, the crystallographic equivalents that are associated with these combinations are defined as indicated above.

Especially the combination (0°, 90°, 0°) (with the associated tolerance range) is distinguished for langatate by a particularly low propagation velocity for surface waves, at just over 2200 m/s, and a coupling factor of 0.54%. This characteristic can, in particular, be utilized to prevent the bulk waves that addtionally occur in the substrate lamina from having an influence on the characteristic of the surface acoustic wave component, e.g. as a resonator. The combinations mentioned above at the second and third points are especially distinguished in that the bulk wave lying closest in terms of frequency lies far away from the frequency of a surface wave, and precisely these cuts are therefore particularly suitable for surface acoustic wave filters with particularly large usable bandwidth. Moreover, a crystal cut with the combination (10°, 140°, 167.5°) has a particularly high coupling factor of as much as 0.7%, at a vanishing beam steering angle, with a wave propagation velocity of about 2540 m/s. The beam steering angle for langatate is not negligible. At the angle combination (40°, 40°, 0°), the beam steering angle is more than 9°.

Singly rotated cuts having the Euler angle λ=0° are advantageous since these cuts are easier to produce than other, so-called doubly rotated cuts. Nevertheless, some doubly rotated cuts have particularly favorable characteristics for substrate laminas made of langatate. The combination (30°,60°, 0°) is distinguished by a negligibly small influence from the closest bulk wave. Its propagation velocity is different by more than 200 m/s than that of a surface wave for an equally large coupling factor at about 0.52%. A combination within the combination (10°, 25° to 45°, 26°), especially with μ=30° has, for a high coupling factor of 0.53%, a propagation velocity for the surface wave of only about 2320 m/s. With this combination as well, the large frequency spacing of the nearest bulk wave guarantees a high usable bandwidth as a surface acoustic wave component (for instance, in comparison with the combination (0°, 90°, 0°)). A combination of the range (20°, 30° to 70°, 17°), especially the combination (20°, 60°, 16°), has a very particularly low propagation velocity of only 2300 m/s.

I claim:

1. A langasite crystal substrate lamina for use in an electronic surface acoustic wave component having crystal cuts which provide a high coupling factor and low surface wave propagation velocity, said substrate lamina having an oriented substrate surface, wherein the surface is defined by Euler angles λ in the range of from 10° to 14°, μ in the range of from 130° to 150° and θ in the range of from above 160° to 175°.

2. The substrate lamina according to claim 1, wherein the substrate surface is defined Euler angles μ=10°, μ=140° and θ=166° and wherein therespective tolerance width for the angles μ and θ is ±5°.

3. A langatate crystal substrate lamina for use in an electronic surface acoustic wave component having crystal cuts which provide a high coupling factor and low surface wave propagation velocity, and substrate lamina having an oriented substrate surface wherein the surface is defined by Euler angles selected from the group consisting of:
(λ=0°±5°; μ=80°−110°; θ=0°±5°)
(λ=0°; μ=20° to 80°, θ=32,5°±5°) and
(λ=0°; μ=130°−150°, θ=155°−180°)
(30°±5°, 60°±5°, 0°±5°)
(10°±5°, 25° to 45°, 26°±5°)
(20°±5°, 30° to 70°, 17°±5°).
